(19) United States
(12) Patent Application Publication
(10) Pub. No.: US 2004/0118501 A1
(43) Pub. Date: Jun. 24, 2004

(54) Heat transfer composite with anisotropic heat flow structure

(75) Inventors: Chia-Pin Chiu, Tempe, AZ (US); Kevin Liao, Fremont, CA (US)

Correspondence Address: SCHWEGMAN, LUNDBERG, WOESSNER & KLUTH, P.A., P.O. BOX 2938, MINNEAPOLIS, MN, 55402, US

(73) Assignee: Intel Corporation

(21) Appl. No.: 10/325,798

(22) Filed: Dec. 19, 2002

(51) Int. Cl. B32B 31/00; H01L 23/34

(52) U.S. Cl. 156/64; 156/250; 257/720

(57) ABSTRACT

A system includes plurality of aligned heat transfer structures in a thermal interface material (TIM) to transfer heat from a die to a heat sink. The system includes a heat transfer subsystem disposed on the backside surface of the die. In one embodiment, the heat transfer subsystem includes a plurality of aligned first heat transfer structures that are anisotropically and discretely disposed in a second heat transfer material. A method of bonding a die to a heat sink uses a die-referenced process as opposed to a substrate-referenced process.

### TECHNICAL FIELD

Disclosed embodiments relate to a heat transfer composite that is a thermal conductive layer. The heat transfer composite includes a plurality of high-thermal conductivity structures that are discretely intermingled with a lower-thermal conductivity material matrix. More particularly, an embodiment relates to aligned, high thermal-conductivity carbon fibers that are used in a heat transfer composite.

### BACKGROUND INFORMATION

### DESCRIPTION OF RELATED ART

An integrated circuit (IC) die is often fabricated into a processor for various tasks. The increasing power consumption of microprocessors results in tighter thermal budgets for a thermal solution design when the processor is employed in the field. Accordingly, a thermal interface is often needed to allow the processor to reject heat more efficiently. Various contrivances have been used to allow the processor to efficiently reject heat.

The most common thermal interface can employ a heat sink such as a heat spreader that is coupled to the backside of a die. One of the issues encountered when using an integrated heat spreader (IHS) is getting a balance between sufficient adhesion to the die, and a high enough heat flow to meet the cooling load of the die. To deal with this issue, several bonding materials have been tried with varying results. If the adhesion is insufficient, the IHS may spall off from the thermal interface material (TIM) and result in a yield issue or a field failure. One technicality encountered is achieving an acceptable IHS standoff from the die and the board to which the board is mounted. Because of various existing processes, a substrate-referenced process is used that may cause a significant variation in bond-line thickness (BLT) between the top of the die and the bonding surface of the IHS.

Thermal interface material BLT is maintained for mechanical reliability of the thermal interface during temperature cycling. Due to the difference in the coefficients of thermal expansion of the IHS and the die, there is a large amount of shear stress that occurs in the TIM. Thicker bond lines can help the TIM to withstand the shear stress, however, they add to the overall package size. A TIM BLT is also an element in the thermal resistance of the thermal interface. A thinner BLT results in a lower thermal resistance, however, it may not have appropriate adhesion to prevent spalling.

Due to these limits in the TIM BLT, which are required for package applications, a TIM BLT must be tightly controlled. A BLT variation of about plus-or-minus 1.5 mils under conventional technology can be too great for some tolerances.

### BRIEF DESCRIPTION OF THE DRAWINGS

In order to understand the manner in which embodiments of the present invention are obtained, a more particular description of various embodiments of the invention briefly described above will be rendered by reference to the appended drawings. Understanding that these drawings depict only typical embodiments of the invention that are not necessarily drawn to scale and are not therefore to be considered to be limiting of its scope, some embodiments of the invention will be described and explained with additional specificity and detail through the use of the accompanying drawings in which:

FIG. 1 is a top-view cross-section of a heat transfer composite according to an embodiment;

FIG. 2 is a top-view cross-section of a heat transfer composite according to another embodiment;

FIG. 3 is a top-view cross-section of a heat transfer composite according to another embodiment;

FIG. 4 is an elevational cross section of a chip package according to an embodiment that includes a heat transfer composite;

FIG. 5 is a top-view cut-away cross-section of a portion of the chip package depicted in FIG. 4 taken along the section line 5-5 according to an embodiment;

FIG. 6 is a cut-away cross-section of a portion of the chip package depicted in FIG. 4 taken along the section line 5-5 according to another embodiment;

FIG. 7A is an elevational cross-section that illustrates an assembly process according to an embodiment;

FIG. 7B is an elevational cross-section of the structure depicted in FIG. 7A after further processing;

FIG. 7C is an elevational cross-section of the structure depicted in FIG. 7B after further processing;

FIG. 8 is a schematic process of assembly of a heat-transfer composite according to an embodiment;

FIG. 9 is a process flow diagram that depicts non-limiting process embodiments; and

FIG. 10 is a method flow diagram that depicts non-limiting method embodiments.

### DETAILED DESCRIPTION

One embodiment relates to a heat transfer structure that includes a plurality of anisotropic heat flow structures. One embodiment relates to a system that includes a thermal interface material (TIM) intermediary that includes a plurality of anisotropic heat flow structures. One embodiment relates to a process of making a composite heat transfer structure. In one embodiment, the TIM is disposed between a heat spreader and a die for heat transfer out of the die. One embodiment includes a method of bonding a die to a heat spreader that uses a die-referenced process as opposed to a substrate-referenced process. One embodiment includes a chip package system.

The following description includes terms, such as upper, lower, first, second, etc. that are used for descriptive purposes only and are not to be construed as limiting. The embodiments of a device or article described herein can be manufactured, used, or shipped in a number of positions and orientations. The terms “die” and “processor” generally refer to the physical object that is the basic workpiece that is transformed by various process operations into the desired integrated circuit device. A board is typically a resin-impregnated fiberglass structure that acts as a mounting substrate for the die. A die is usually singulated from a wafer, and wafers may be made of semiconducting, non-semiconducting, or combinations of semiconducting and non-semiconducting materials.

Reference will now be made to the drawings wherein like structures will be provided with like reference designations. In order to show the structures of embodiments most clearly, the drawings included herein are diagrammatic representations of inventive articles. Thus, the actual appearance of the fabricated structures, for example in a photomicrograph, may appear different while still incorporating the essential structures of embodiments. Moreover, the drawings show only the structures necessary to understand the embodiments. Additional structures known in the art have not been included to maintain the clarity of the drawings.

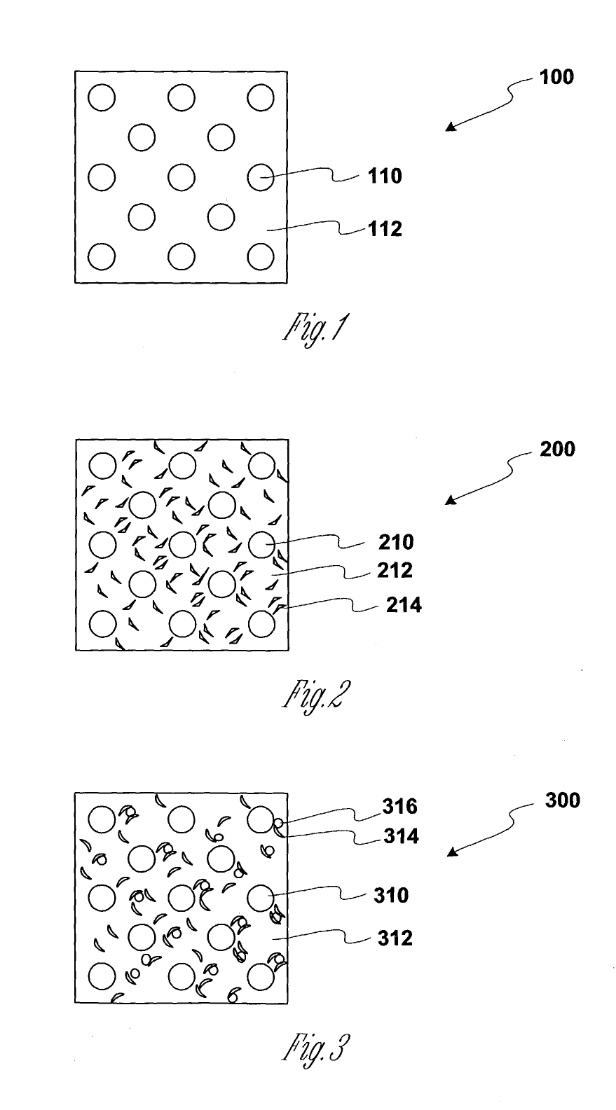

FIG. 1 is a top-view cross-section of a heat transfer composite that is an interface subsystem 100 according to an embodiment. The interface subsystem 100 is applicable to various chip packaging systems according to embodiments set forth herein and their art-recognized equivalents that become apparent after understanding this disclosure.

According to various embodiments, the interface subsystem 100 is a combination of a plurality of first heat transfer structures 110 and a second heat transfer structure 112 that acts as a matrix for the plurality of first heat transfer structures 110. In one embodiment, the plurality of first heat transfer structures 110 have a coeffecient of thermal conductivity in a range from about 90 Watt per meter degree Kelvin (W/m-K) to about 700 W/m-K.

The plurality of first heat transfer structures 110 are depicted as circular cross-sections of elongatged fibers that pass orthogonal to the plane of the FIG. The plurality of first heat transfer structures are depicted as arranged in a pattern, but this pattern is only one embodiment, as other arrangements can be implemented. Further, the plurality of first heat transfer structures 110 is not necessarily drawn to scale. In one embodiment, the interface subsystem 100 depicted in FIG. 1 is a section taken from a larger article. In one embodiment, the diameter of a given first heat transfer structure 110 is in a range from about 1 micron to about 1,000 micron. In another embodiment, each occurrence of the plurality of first heat transfer structures 110 represents a bundle of high-thermal conductivity fibers.

In one embodiment, the plurality of first heat transfer structures 110 represents a bundle of high-thermal conductivity fibers such as metal filaments. In one embodiment, the plurality of first heat transfer structures 110 represents a bundle of high-thermal conductivity fibers such as glass fibers. In one embodiment, the plurality of first heat transfer structures 110 represents a bundle of high-thermal conductivity fibers that include graphite fibers. In one embodiment, the plurality of first heat transfer structures 110 represents a bundle of high-thermal conductivity fibers that include graphite fibers and metal filaments. In one embodiment, the plurality of first heat transfer structures 110 represents a bundle of high-thermal conductivity fibers that include graphite fibers and glass fibers. In one embodiment, the plurality of first heat transfer structures 110 represents a bundle of high-thermal conductivity fibers that include metal filaments and glass fibers. In one embodiment, all three of metal, glass, and graphite fibers are included. Various article qualities can be achieved by selecting at least one of a graphite, metal, and glass fiber and fixing at lest one of them in a second heat transfer structure 112 such as the matrix depicted in FIG. 1.

In one embodiment, the bundle is impregnated with a binder that can be an organic matrix. In one embodiment, the bundle is impregnated with a binder that can be metallic. As set forth below, the impregnating composition can be the same material as the matrix material that contains the fibers.

In one embodiment, the plurality of first heat transfer structures 110 includes a plurality of elongate, aligned thermal conductive structures. Where the term “aligned” is used, it is noted that aligned can mean substantially parallel. Similarly, where the term “aligned” is used, it is noted that a heat flow quality of an aligned plurality of heat transfer structure is substantially anisotropic conductive heat flow in the direction of the parallel orientation.

In one embodiment, the plurality of first heat transfer structures 110 includes a plurality of elongate, aligned carbon fibers. In one embodiment, the plurality of first heat transfer structures 110 includes a plurality of elongate, aligned graphite fibers such as are manufactured by Mitsubishi Chemical America, of White Plains, N.Y. In one embodiment, the plurality of first heat transfer structures 110 include graphite fibers with a coeffecient of thermal conductivity in a range from about 500 W/m-K to about 700 W/m-K. In one embodiment, the plurality of first heat transfer structures 110 include graphite fibers with a coeffecient of thermal conductivity of about 600 W/m-K.

The plurality of first heat transfer structures 110 and the second heat transfer structure 112 form a first heat transfer composite shape. The shape is depicted in FIG. 1 as rectangular, but other shapes can be achieved such as circular, eccentric, or arbitrary shapes according to preferences and specific processing conditions and specific assembly methods. In one embodiment, the first heat transfer composite shape is severed from a supply stock that has been either continuously, semi-continuously, or batch processed as set forth herein. When the first heat transfer composite shape is therefore viewed end-on as depicted in FIG. 1, and after a portion has been severed, it becomes a second heat transfer composite shape that is the interface subsystem 100.

In one embodiment, the second heat transfer composite shape that is the interface subsystem 100 has a thickness in a range from about 0.1 mil to about 100 mil. Although the plurality of first heat transfer structures 110 are depicted as spaced apart in the matrix that is the second heat transfer structure 112, in one embodiment, the plurality of first heat transfer structures 110 can be touching each other in a close-packed configuration, and the second heat transfer structure 112 acts as an interstitial matrix.

In one embodiment, the second heat transfer structure 112 that forms the matrix for the plurality of first heat transfer structures 110 is a metal alloy with a coeffecient of thermal conductivity in a range from about 30 W/m-K to about 90 W/m-K. In one embodiment, the second heat transfer structure 112 is a Pb-containing solder. In one embodiment, the second heat transfer structure 112 is a substantially Pb-free solder. One example of a Pb-containing solder includes a tin-lead solder. In selected embodiments, Pb-containing solder is a tin-lead solder composition such as from 97% tin (Sn)/3% lead (Sn3Pb). A tin-lead solder composition that may be used as the second heat transfer structure 112 is a Sn63Pb composition of 37% tin/63% lead. In any event, the Pb-containing solder may be a tin-lead solder comprising SnxPby, wherein x+y total 1, and x is in a range from about 0.3 to about 0.99. In one embodiment, the Pb-containing solder is a tin-lead solder composition of Sn3Pb for the second heat transfer structure 112. In another embodiment, the Pb-containing solder is a tin-lead solder composition of Sn63Pb.

In one embodiment, the second heat transfer structure 112 is an organic composition such as a high thermal conductivity polymer with a coeffecient of thermal conductivity in a range from about 0.1 W/m-K to about 1 W/m-K.

The combination of the plurality of first heat transfer structures 110 and the second heat transfer structure 112 presents a conglomerate channel from one surface of the interface subsystem 100 to an opposite surface thereof. As such, heat transfer through the matrix is expedited.

FIG. 2 is a cross-section of a heat transfer composite according to another embodiment. An interface subsystem 200 is provided according to an embodiment. The interface subsystem 200 is applicable to various chip packaging systems according to embodiments set forth herein and their art-recognized equivalents that become apparent after understanding this disclosure.

According to various embodiments, the interface subsystem 200 is a combination of a plurality of first heat transfer structures 210 and a second heat transfer structure 212 that acts as a matrix for the plurality of first heat transfer structures 210. Additionally, a plurality of first particulates 214 is interspersed within the second heat transfer structure 212.

In one embodiment, the second heat transfer structure 212 that forms the matrix for the plurality of first heat transfer structures 210 is a metal alloy according to various embodiment set forth herein. In one embodiment, the second heat transfer structure 212 is an organic composition according to various embodiment set forth herein.

In one embodiment, the second heat transfer structure 212 that forms the matrix for the plurality of first heat transfer structures 210 is a metal alloy with a coefficient of thermal conductivity in a range from about 30 W/m-K to about 90 W/m-K. In one embodiment, the second heat transfer structure 212 is an organic composition such as a high thermal conductivity polymer with a coefficient of thermal conductivity in a range from about 0.1 W/m-K to about 1 W/m-K.

The plurality of first particulates 214 can be interspersed in the matrix of the second heat transfer structure 212 for various functions. In one embodiment, the plurality of first particulates 214 includes inorganics that have a coefficient of thermal expansion (“CTE”) that, when mixed into the matrix of the second heat transfer structure 212, results in an overall CTE for the interface subsystem 200 that is close to the CTEs of articles to which the interface subsystem 200 is contemplated for attachment. For example, where the interface subsystem 200 is to be attached between a die and a heat sink, the overall CTE is selected to be greater that one of the die and the heat sink, but less than the other.

In one embodiment, the plurality of first particulates 214 includes inorganics that are metallic in an organic matrix of the second heat transfer structure 212. In this embodiment, the overall coefficient of thermal conductivity for the interface subsystem 200 is in a range from about 0.1 W/m-K to less than or equal to about 600 W/m-K.

In one embodiment, the plurality of first particulates 214 includes inorganics that are metallic in a metallic matrix of the second heat transfer structure 212. In this embodiment, the overall coefficient of thermal conductivity for the interface subsystem 200 is in a range from about 20 W/m-K to less than or equal to about 600 W/m-K.

In one embodiment, the plurality of first particulates 214 includes inorganics that are dielectrics in an organic matrix of the second heat transfer structure 212. In this embodiment, the overall coefficient of thermal conductivity for the interface subsystem 200 is in a range from about 10 W/m-K to about 90 W/m-K.

In one embodiment, the plurality of first particulates 214 includes inorganics that are dielectrics in a metallic matrix of the second heat transfer structure 212. In this embodiment, the overall coefficient of thermal conductivity for the interface subsystem 200 is in a range from about 20 W/m-K to less than or equal to about 600 W/m-K.

The heat transfer composite depicted in FIG. 2 represents another interface subsystem 200 according to an embodiment. Although the plurality of first particulates 214 is depicted as angular and eccentric shapes, in one embodiment, the plurality of first particulates 214 can be other shapes. In one embodiment, the plurality of first particulates 214 is a substantially spherical powder that has an average diameter in a range from about 0.1 micron to about 10 micron. In one embodiment, the eccentricity of the particulates 214, as measured by a ratio of the major diagonal axis to the minor diagonal axis, is in a range from about 1 to about 10. In one embodiment, the eccentricity is greater than 10.

The combination of the plurality of first heat transfer structures 210, the second heat transfer structure 212, and the plurality of first particulates 214 presents a conglomerate channel from one surface of the interface subsystem 200 to an opposite surface thereof. As such, heat transfer through the matrix is expedited.

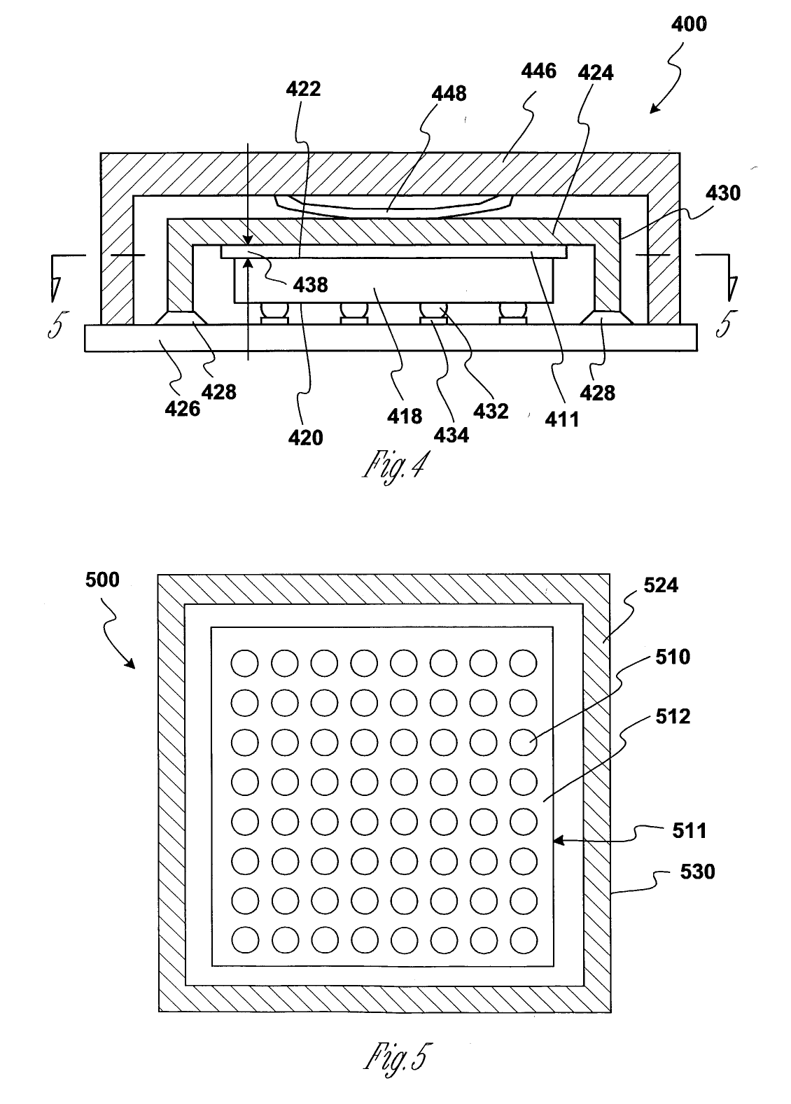

FIG. 3 is a cross-section of a heat transfer composite according to another embodiment. An interface subsystem 300 is depicted that is applicable to various chip packaging systems according to embodiments set forth herein and their art-recognized equivalents that become apparent after understanding this disclosure.

According to various embodiments, the interface subsystem 300 is a combination of a plurality of first heat transfer structures 310 and a second heat transfer structure 312 that acts as a matrix for the plurality of first heat transfer structures 310. A plurality of first particulates 314 is interspersed within the second heat transfer structure 312. Additionally, a plurality of second particulates 316 is also interspersed within the second heat transfer structure 312. Similar to the plurality of first particulates 314, the plurality of second particulates 316 can have a similar eccentricity ratio. The two eccentricities can be related or they can be independent of each other.

In one embodiment, the second heat transfer structure 312 that forms the matrix for the plurality of first heat transfer structures 310 is a metal alloy according to various embodiments set forth herein. In one embodiment, the second heat transfer structure 312 is an organic composition according to various embodiments set forth herein.

In one embodiment, the plurality of first particulates 314 is a first metal, and the plurality of second particulates 316 is a second metal. In this embodiment, the overall coefficient of thermal conductivity for the interface subsystem 300 is in a range from about 20 W/m-K to less than or equal to about 600 W/m-K.

In one embodiment, the plurality of first particulates 314 is a first dielectric, and the plurality of second particulates 316 is a second dielectric. In this embodiment, the overall coefficient of thermal conductivity for the interface subsystem 300 is in a range from about 5 W/m-K to less than or equal to about 600 W/m-K.

In one embodiment, the plurality of first particulates 314 is a dielectric, and the plurality of second particulates 316 is a metal. In this embodiment, the overall coefficient of thermal conductivity for the interface subsystem 300 is in a range from about 20 W/m-K to less than or equal to about 600 W/m-K.

In one embodiment, the plurality of first particulates 314 is a metal, and the plurality of second particulates 316 is a dielectric. In this embodiment, the overall coefficient of thermal conductivity for the interface subsystem 300 is in a range from about 20 W/m-K to less than or equal to about 600 W/m-K.

Although the shapes for the plurality of first particulates 314 and the plurality of second particulates 316 are respectively depicted as eccentric and round, it should be appreciated that these shapes are depicted to distinguish the two particulate types. In one embodiment, the plurality of second particulates 316 is depicted as having reflowed under a thermal load and has at least partially wetted contiguous occurrences of the plurality of first particulates 314.

The combination of the plurality of first heat transfer structures 310, the second heat transfer structure 312, the plurality of first particulates 314, and the plurality of second particulates 316 presents a conglomerate channel from one surface of the interface subsystem 300 to an opposite surface thereof. As such, heat transfer through the matrix is expedited.

FIG. 4 is an elevational cross section of a chip package 400 that includes an interface subsystem 411 that is a heat transfer composite according to an embodiment as set forth herein. The chip package 400 includes a die 418 with an active surface 420 and a backside surface 422. The die 418 is connected to a thermal management device. In one embodiment, the thermal management device is an integrated heat spreader (IHS) 424 that is disposed above the backside surface 422 of the die 418. An interface subsystem 411, in the form of a TIM such as any of the interface subsystem 100 (FIG. 1), the interface subsystem 200 (FIG. 2), or the interface subsystem 300 (FIG. 3), in their various embodiments, is disposed between the backside surface 422 of the die and the IHS 424.

It is noted in FIG. 4, the IHS 424 is attached to a mounting substrate 426 with a bonding material 428 that secures a lip portion 430 of the IHS 424 thereto. The mounting substrate 426 is a printed circuit board (PCB), such as a main board, a motherboard, a mezzanine board, an expansion card, or another mounting substrate with a specific application.

In one embodiment, the thermal management device is a heat sink without a lip structure such as a simple planar heat sink. In one embodiment the thermal management device includes a heat pipe configuration. It is noted in FIG. 4 that the die 418 is disposed between the interface subsystem 411 and a series of electrical bumps 432 that are in turn each mounted on a series of bond pads 434. The electrical bumps 432 make contact with the active surface 420 of the die 418. By contrast, the interface subsystem 411 makes thermal contact with the backside surface 422 of the die 418. A bond-line thickness (BLT) 438 is depicted. The BLT is the thickness of the interface subsystem. In one embodiment, the BLT is in a range from about 100 Å to about 1,000 microns.

FIG. 4 illustrates a bonding material 428 that fastens the lip portion 430 of the IHS 424 to the mounting substrate 426. Additionally, the electrical bumps 432 are depicted in a ball grid array as is known in the art.

As depicted in FIG. 4, the interface subsystem 411 can include a metal matrix that is the second heat transfer structure 112 (e.g., FIG. 1). In one embodiment, the second heat transfer structure 112 includes a reactive solder. A reactive solder material includes properties that allow for adhesive and/or heat-transfer qualities. For example, the reactive solder material can melt and resolidify without a pre-flux cleaning that was previously required. Further, a reactive solder embodiment can also include bonding without a metal surface. Without the need of a metal surface for bonding, processing can be simplified.

In one embodiment, a reactive solder includes a base solder that is alloyed with an active element material. In one embodiment, a base solder is indium. In one embodiment, a base solder is tin. In one embodiment, a base solder is silver. In one embodiment, a base solder is tin-silver. In one embodiment, a base solder is at least one lower-melting-point metal with any of the above base solders. In one embodiment, a base solder is a combination of at least two of the above base solders. Additionally, conventional lower-melting-point metals/alloys can be used.

The active element material is alloyed with the base solder. In one embodiment, the active element material is provided in a range from about 2% to about 30% of the total solder. In one embodiment, the active element material is provided in a range from about 2% to about 10%. In one embodiment, the active element material is provided in a range from about 0.1% to about 2%.

Various elements can be used as the active element material. In one embodiment, the active element material is selected from hafnium, cerium, lutetium, other rare earth elements, and combinations thereof. In one embodiment, the active element material is a refractory metal selected from titanium, tantalum, niobium, and combinations thereof. In one embodiment, the active element material is a transition metal selected from nickel, cobalt, palladium, and combinations thereof. In one embodiment, the active element material is selected from copper, iron, and combinations thereof. In one embodiment, the active element material is selected from magnesium, strontium, cadmium, and combinations thereof.

The active element material when alloyed with the base solder can cause the alloy to become reactive with a semiconductive material such as the backside surface 422 of the die 418. The alloy can also become reactive with an oxide layer of a semiconductive material such as silicon oxide, gallium arsenide oxide, and the like. The alloy can also become reactive with a nitride layer of a semiconductive material such as silicon nitride, silicon oxynitride, gallium arsenide nitride, gallium arsenide oxynitride, and the like.

Reaction of the alloy with the die 418 can be carried out by thermal processing. Heat can be applied by conventional processes, such that the active element materials reach the melting zone of the base solder. For example, where the base solder includes indium, heating is carried out in a range from about 150° C. to about 200° C.

During reflow of the alloy, the active element(s) dissolve and migrate to the backside surface 422 of the die 418. Simultaneously, the base solder bonds to the IHS 424. It is not necessary that the backside surface 422 be metalized prior to soldering. The solder joint (not depicted) that is formed by the reactive solder material can display a bond strength in a range from about 1,000 psi and about 2,000 psi.

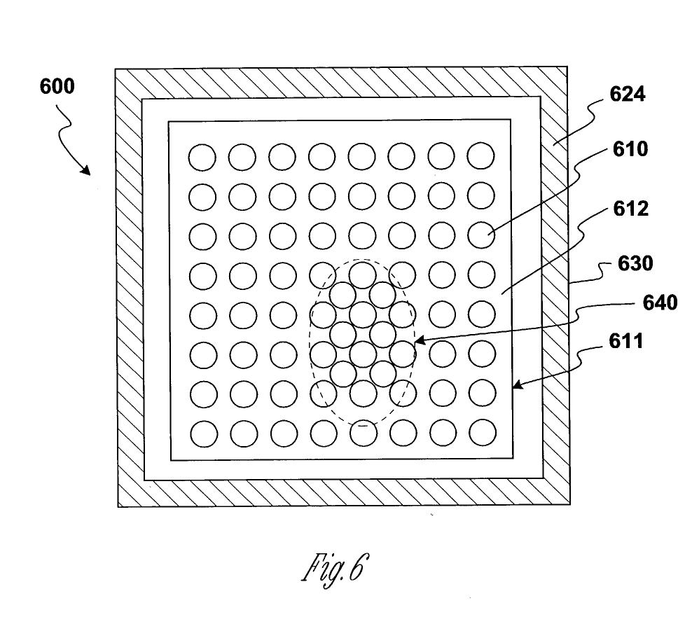

FIG. 5 is a top-view cut-away cross-section of a portion of a chip package 500, such as is depicted in FIG. 4 taken along the section line 5-5 according to an embodiment. The cross-section reveals a plurality of first heat transfer structures 510 and a second heat transfer structure 512 that acts as a matrix for the plurality of first heat transfer structures 510 according to various embodiments set forth herein. Together, the plurality of first heat transfer structures 510 and the second heat transfer structure 512 constitute an interface subsystem 511. In one embodiment, the plurality of first heat transfer structures and the second heat transfer structure constitute the interface subsystem 200 depicted in FIG. 2 according to various embodiments. In one embodiment, the plurality of first heat transfer structures and the second heat transfer structure constitute the interface subsystem 300 depicted in FIG. 3 according to various embodiments.

In FIG. 5, the lip portion 530 of the integrated heat spreader 424 (FIG. 4) is exposed. Additionally, FIG. 5 depicts a cross-section of the interface subsystem 511, which in this embodiment includes a pattern of the plurality of first heat transfer structures 510 and that are discretely disposed within the second heat transfer structure 512.

FIG. 6 is a top-view cut-away cross-section of a portion of the chip package depicted in FIG. 4 taken along the section line 5-5 according to another embodiment. The cross-section reveals a plurality of first heat transfer structures 610 and a second heat transfer structure 612 that acts as a matrix for the plurality of first heat transfer structures 610 according to various embodiments set forth herein. Together, the plurality of first heat transfer structures 610 and the second heat transfer structure 612 constitute an interface subsystem 611. In one embodiment, the plurality of first heat transfer structures and the second heat transfer structure constitute the interface subsystem 200 depicted in FIG. 2 according to various embodiments. In one embodiment, the plurality of first heat transfer structures and the second heat transfer structure constitute the interface subsystem 300 depicted in FIG. 3 according to various embodiments.

FIG. 6 depicts the lip portion 630 of the integrated heat spreader 624. Additionally, FIG. 6 depicts a cross-section of the interface subsystem 611, which in this embodiment includes a pattern of the plurality of first heat transfer structures 610 and that are discretely disposed within the second heat transfer structure 612. Additional to this embodiment is a concentration region 640 of the interface subsystem 611. In the concentration region 640, a higher density occurs for the plurality of first heat transfer structures 610. In one embodiment, the concentration region 640 is configured to be located proximate an excessively hot region of a die to facilitate heat removal. For example, a level zero cache (“L0 cache”) can be located on a die that has a high frequency of access and accompanying heat generation. By concentrating more of the plurality of heat transfer structures 610 in a concentration region 640 that will be aligned with the die at a more active region, a more efficient heat transfer conduit is provided, but adhesion of the interface subsystem 611 to a die and heat sink is not compromised, due to sufficient amounts of the second heat transfer structure 612 that is adhering to the die and the heat sink. This larger heat transfer capability in the concentration region 640 represents a lowered resistance to heat flow between the heat-generating die and the heat-removing heat spreader.

Another embodiment relates to a die system. An embodiment of the die system is depicted in some of the structures illustrated in FIGS. 1-6 by way of non-limiting examples. With reference to FIG. 4, in one embodiment, the die system includes the die 418 and the interface subsystem 411 as set forth herein according to the various embodiments. Further, the die system in one embodiment includes the interface subsystem 411. In another embodiment, the die system includes the plurality of first heat transfer structures that has a discrete patterning upon the die backside surface 422. The discrete patterning is a subset embodiment of the chip package 400, as depicted in FIG. 4.

The die system in another embodiment includes the mounting substrate 426 disposed below the die 418. In other words, the die 418, the electrical bumps 432, and their bond pads 434 as mounted upon the mounting substrate 426, represent a package precursor according to this embodiment. In another embodiment, the die system includes the mounting substrate 426 and other structures as set forth herein and the integrated heat spreader 424 disposed above the die 418. As depicted in FIG. 4, the interface subsystem 411 is disposed between the die 418 and the integrated heat spreader 424.

Another embodiment relates to a thermal interface alone as depicted in FIG. 1 (interface subsystem 100), FIG. 2 (interface subsystem 200), FIG. 3 (interface subsystem 300), and FIG. 4 (interface subsystem 411). According to an embodiment, interface subsystem has a characteristic thickness that is in a range from about 0.1 micron to about 25 micron. The characteristic thickness is selected to achieve a preferred bond line thickness (BLT) as is understood in the art. Referring to FIG. 4, the BLT 438 in this embodiment closely tracks the characteristic thickness of the interface subsystem 411. In other words, the BLT 438 has substantially the same thickness as the interface subsystem 411. In one embodiment, the BLT 438 is in a range from about 1 mil to about 25 mils. In one embodiment, the BLT 438 is in a range from about 2 mils to about 10 mils. In another embodiment, the BLT 438 is in a range from about 10 mils to about 20 mils.

In another embodiment that relates to the thermal interface either alone, or applied in a chip package, the plurality of first heat transfer structures 110 (FIG. 1, for example) is present in relation to the second heat transfer structure 112 in a volume range from about 0.1% to about 5%. In another embodiment, the plurality of first heat transfer structures 110 (FIG. 1, for example) is present in relation to the second heat transfer structure 112 in a volume range from about 0% to about 0.1%. In another embodiment, the plurality of first heat transfer structures 110 is present in relation to the second heat transfer structure 112 in a volume range from about 0% to about 100%. In another embodiment, the plurality of first heat transfer structures 110 is present in relation to the second heat transfer structure 112 in a volume range from about 2% to about 10%.

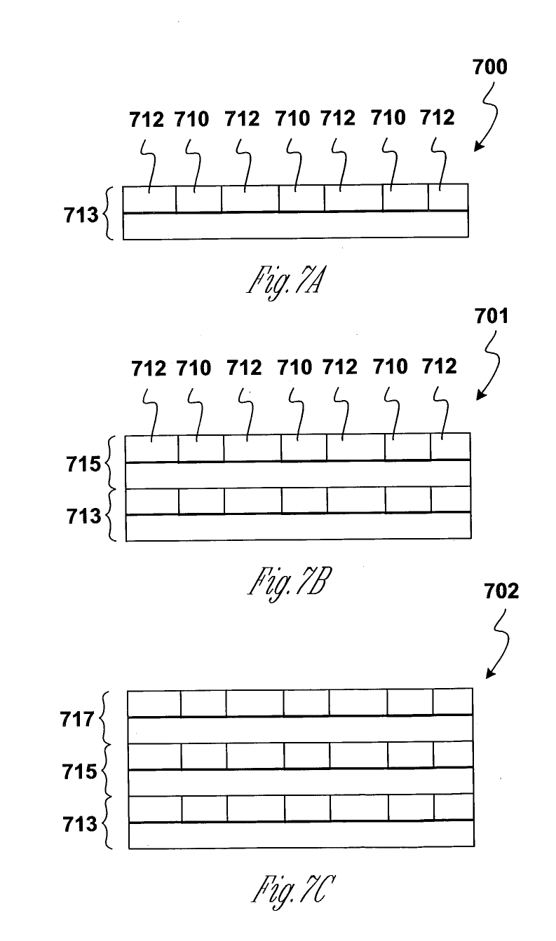

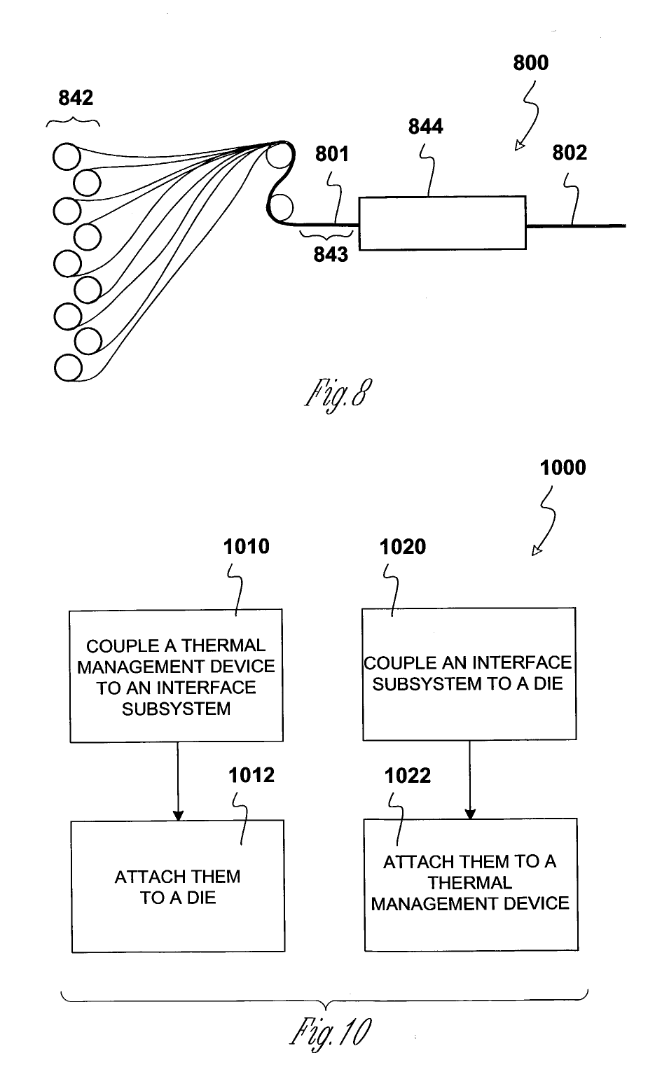

FIG. 7A is an elevational cross-section of a heat transfer structure composite assembly process according to an embodiment. Interface subsystem embodiments can be manufactured by a variety of processes. In one embodiment, a laminated interface subsystem 700 is fabricated by assembling plurality of first heat transfer structures 710 within a matrix of second heat transfer structures 712. FIG. 7A depicts a preliminary layer 713 of a laminated interface subsystem 700. The various embodiments of the plurality of first heat transfer structures combined with the various second heat transfer structures as set forth herein, are applicable to modify these embodiments. Additionally, although not depicted, the plurality of first particulates and optionally the plurality of second particulates can be pre-inserted into the second heat transfer structure 712.

FIG. 7B is an elevational cross-section of the structure depicted in FIG. 7A after further processing. Lamination has proceeded to begin a subsequent layer 715 of the laminated interface subsystem 701.

FIG. 7C is an elevational cross-section of the structure depicted in FIG. 7B after further processing. Lamination has proceeded to begin an upper layer 717 of the laminated interface subsystem 702 that can achieve a first heat transfer composite shape. It can be appreciated that a laminate of this type can be assembled seriatim until a laminate of a selected configuration of a first heat transfer composite shape 702 has been achieved.

Processing of the interface subsystem 702 can be continued by a thermal treatment in which the matrix of second heat transfer structures 712 is melted and/or cured in a manner to secure the plurality of first heat transfer structures 710 within the matrix. In one embodiment, this processing is done before severing a portion of a bulk laminate that results in the second heat transfer composite shape that makes the interface subsystem 702. Although the structures depicted in FIG. 7C are substantially rectilinear, this depiction is not to be limiting of various lamination embodiments that can be applied. Further, although spacing of the plurality of first heat transfer structures 710 and the second heat transfer structure 712 is depicted to be substantially uniform, other non-uniform and/or concentration region configurations can be made.

FIG. 8 is a schematic process 800 of assembly of a heat-transfer composite 802 according to an embodiment. Alternative to a seriatim lamination process, a simultaneous lamination process can also be carried out. A plurality of precursor fibers 842 is supplied to a processor 844 that can arrange a selected pattern(s) according to embodiments set forth herein and further according to specific applications. Alternatively, the plurality of precursor fibers 842 can include both the plurality of first heat transfer structures 810 (not specified) and the second heat transfer structures 812 (not specified) that are melted into the plurality of first heat transfer structures 810 (not specified). Alternatively or additionally, the processor 844 can heat treat the laminate 801 to result in a first heat transfer composite shape 802. Thereafter, the first heat transfer composite shape 802 can be severed to a thickness according to a specific application.

Although FIG. 8 depicts a continuous process, by reading the disclosure, it can be appreciated that a semicontinuous process can include taking a section 843 of an uncured/unmelted laminate 801 and semicontinuously processing it in a processor 844 according to the various semicontinuous processing arts. It can be further appreciated that a batch process can include taking a section 843 of an uncured/unmelted laminate 801 and batch processing it in a processor 840 according to the various batch processing arts.

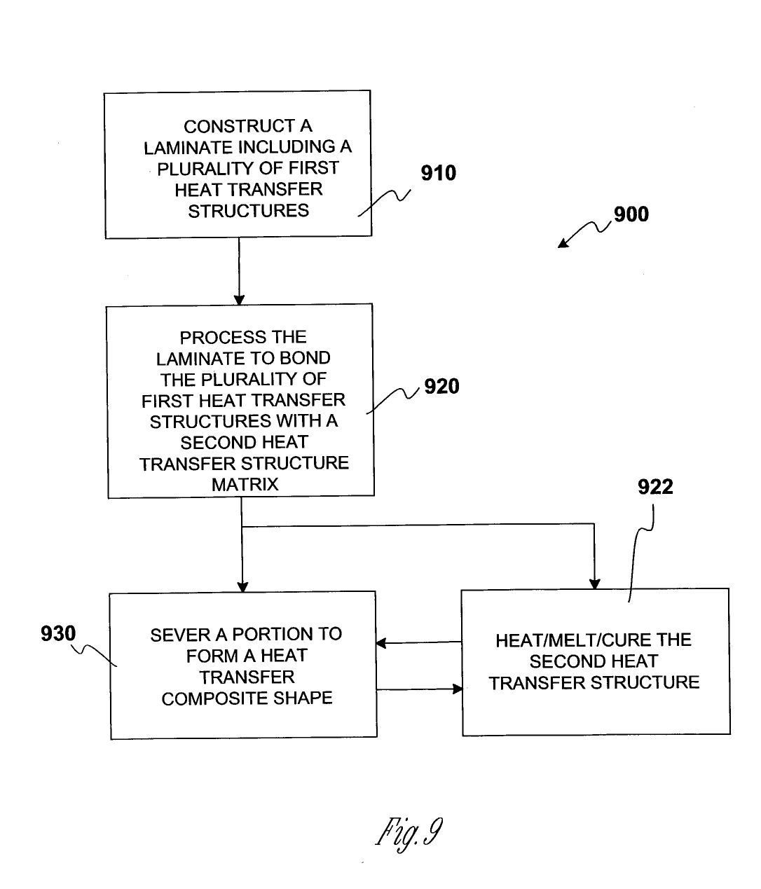

FIG. 9 is a process flow diagram 900 that depicts non-limiting process embodiments. At 910, a laminate is constructed. Although FIGS. 7 and 8 have depicted various lamination embodiments, other processes can be done to achieve a first heat transfer composite shape. For example, the section 843 can be a plurality of first heat transfer structures that is drawn through a molten second transfer structure precursor in a processor 844.

At 920, the laminate or other plurality of precursor fibers is processed to bond the second heat transfer structure into the plurality of first heat transfer structures according to embodiments set forth herein to form a first heat transfer composite shape.

At 930, the first heat transfer composite structure is severed to form the second heat transfer composite shape such as the interface subsystem 511 by way of non-limiting example.

At 922, an alternative process flow is carried out. At 920, only partial or initial melting and/or curing of the second heat transfer structure is done, followed by more thorough melting and/or curing. Additionally, a process flow can proceed from 930 back to 922 when curing and/or melting can follow severing. One example is the use of a reactive solder that melts at least twice during processing.

FIG. 10 is a method flow diagram 1000 that depicts non-limiting method embodiments. A method embodiment relates to packaging process embodiments that includes bringing an integrated heat spreader and a die into TIM intermediary contact through an interface subsystem to achieve a BLT according to embodiments set forth herein. According to the various method flow embodiments, the interface subsystem may be configured partially on the integrated heat spreader, partially on the die, entirely on the integrated heat spreader, or entirely on the die.

In one method flow embodiment, a die is contacted with the interface subsystem at 1010. In this embodiment, the interface subsystem is disposed first against the integrated heat spreader, followed by disposition of the interface subsystem against the die at 1012. Alternatively, the interface subsystem in one embodiment is disposed first against the die at 1020, followed by disposition of the interface subsystem against the integrated heat spreader at 1022.

As depicted in the various process flow embodiments depicted in FIG. 10, it is noted that the die 418 (FIG. 4) is previously disposed upon a mounting substrate 426 (also FIG. 4). Further as depicted in FIG. 4, it is noted that an integrated heat spreader clip 446 is used to impart a pressure to the die-interface-heat spreader at least partially through a spring 448. Depending upon the combination of interface subsystem and other factors such as adhesive gelling time, organic curing time, metal reflow time, and others, the exact tension of the spring 448 is selected to the requirements of a given packaging system.

According to an embodiment, the bonding method of bringing an integrated heat spreader and a die into intermediary contact through an interface subsystem 100, 200, 300, 411, 511, 611, 702, and 802 in their various embodiments is referred to as a die-referenced process. The die-referenced process relates to the situation that the die 418 (FIG. 4) is already affixed upon the mounting substrate 426. And as in some embodiments, the interface subsystem 411 (FIG. 4) is disposed between the integrated heat spreader 424 and the backside surface 422 of the die 418 while tensing the system with the spring 448. Accordingly, the variability in bonding thickness may often largely be in the flowability of the bonding material that is the second heat transfer structure 412 and its optional particulate additive as it bridges the space between the lip portion 430 of the integrated heat spreader 424 and the mounting substrate 426.

In a general embodiment, after bringing the integrated heat spreader into intermediary contact with the die through the interface subsystem according to various embodiments, bonding the interface subsystem includes reflowing the metal embodiment of the second heat transfer structure, and/or curing an organic embodiment of the second heat transfer structure. Where the bonding interface subsystem includes an organic material, a curing and/or hardening process is carried out after bringing the structures together. Where the bonding interface subsystem includes an organic/inorganic composite, curing, hardening, and/or reflowing can be carried out after bringing the structures together.

It is emphasized that the Abstract is provided to comply with 37 C.F.R. §1.72(b) requiring an Abstract that will allow the reader to quickly ascertain the nature and gist of the technical disclosure. It is submitted with the understanding that it will not be used to interpret or limit the scope or meaning of the claims.

In the foregoing Detailed Description, various features are grouped together in a single embodiment for the purpose of streamlining the disclosure. This method of disclosure is not to be interpreted as reflecting an intention that the claimed embodiments of the invention require more features than are expressly recited in each claim. Rather, as the following claims reflect, inventive subject matter lies in less than all features of a single disclosed embodiment. Thus the following claims are hereby incorporated into the Detailed Description of Embodiments of the Invention, with each claim standing on its own as a separate preferred embodiment.

It will be readily understood to those skilled in the art that various other changes in the details, material, and arrangements of the parts and method stages which have been described and illustrated in order to explain the nature of this invention may be made without departing from the principles and scope of the invention as expressed in the subjoined claims.

What is claimed is:

1. A process of forming a heat transfer composite comprising:
aligning a plurality of first heat transfer structures;
locating a second heat transfer structure adjacent to the plurality of first heat transfer structures;
forming a first heat transfer composite shape from the first heat transfer structures and the second heat transfer structures; and
severing a portion of the first heat transfer composite shape to form a second heat transfer composite shape.

2. The process according to claim 1, wherein the plurality of first heat transfer structures includes a plurality of carbon fibers, and wherein the second heat transfer structure includes a metal, the method further including:
during forming, melting the metal into the plurality of first heat transfer structures; and
optionally curing the first heat transfer composite shape.

3. The process according to claim 1, wherein the plurality of first heat transfer structures includes a plurality of carbon fibers, and wherein the second heat transfer structure includes a metal, the method further including:
assembling the second heat transfer structure and at least one of a die, a heat spreader, and a heat sink; and
bonding the second heat transfer structure to the at least one of a die, a heat spreader, and a heat sink.

4. The process according to claim 1, wherein the plurality of first heat transfer structures includes a plurality of carbon fibers, and wherein the second heat transfer structure includes an organic, the method further including:
during forming, melting the organic into the plurality of first heat transfer structures; and
optionally curing the first heat transfer composite shape.

5. The process according to claim 1, wherein the plurality of first heat transfer structures includes a plurality of carbon fibers, and wherein the second heat transfer structure includes an organic, the method further including:
assembling the second heat transfer structure and at least one of a die, a heat spreader, and a heat sink; and
bonding the second heat transfer structure to the at least one of a die, a heat spreader, and a heat sink.

6. The process according to claim 1, wherein the plurality of first heat transfer structures includes a plurality of carbon fibers, and wherein the second heat transfer structure includes at least one of a metal, an organic, an inorganic dielectric, and a metal-organic composite, the method further including:
during forming, melting the second heat transfer structure into the plurality of first heat transfer structures; and
optionally curing the first heat transfer composite shape.

7. The process according to claim 1, wherein the plurality of first heat transfer structures includes a plurality of carbon fibers, and wherein the second heat transfer structure includes at least one of a metal, an organic, an inorganic dielectric, and a metal-organic composite, the method further including:
assembling the second heat transfer structure and at least one of a die, a heat spreader, and a heat sink; and
bonding the second heat transfer structure to the at least one of a die, a heat spreader, and a heat sink.

8. The process according to claim 1, wherein the first heat transfer composite shape includes an elongate composite, severing including:
cutting a shape from first heat transfer composite shape to form the second heat transfer composite shape.

9. A method of assembling a chip package, comprising:
affixing an article to a heat transfer composite shape, wherein the article is selected from at least one of a die, a heat spreader, and a heat sink, the heat transfer composite shape including:
a plurality of anisotropic first heat transfer structures;
a second heat transfer structure matrix selected from a metal, an organic, an inorganic dielectric, and a metal-organic composite and combinations thereof, and
bonding the article to the first heat transfer composite shape.

10. The method according to claim 9, wherein the article includes a die, the method further including:
bonding the die and the heat transfer composite shape to one of a heat sink, and a heat spreader.

11. The method according to claim 9, wherein the article includes one of a heat sink and a heat spreader, the method further including:
bonding the article and the heat transfer composite shape to one a die.

12. A packaging system comprising:
a die including a backside surface;
a thermal management device above the backside surface; and
an interface subsystem between the backside surface and the thermal management device, wherein the interface subsystem includes:
a plurality of aligned first heat transfer structures;
a second heat transfer structure, wherein the plurality of aligned first heat transfer structures is discretely disposed in the second heat transfer structure.

13. The packaging system according to claim 12, the system further including:
at least one particle in the second heat transfer structure, selected from a metal, an inorganic, an inorganic dielectric, an organic, and a combination thereof.

14. The packaging system according to claim 13, wherein the thermal management device is selected from an integrated heat spreader, a planar heat sink, a heat pipe, and combinations thereof.

15. The packaging system according to claim 13, wherein the plurality of first fibers are concentrated in at least one portion of the second heat transfer structure in a concentration region.

16. An integrated heat spreader system comprising:
a heat spreader body having a recess;
an interface subsystem in the recess, wherein the interface subsystem includes:
a plurality of aligned first heat transfer structures;
a second heat transfer structure, wherein the plurality of aligned first heat transfer structures is discretely disposed in the second heat transfer structure.

17. The integrated heat spreader system according to claim 16, further including:
a die including a backside surface, wherein the backside surface is against the interface subsystem.

18. The integrated heat spreader system according to claim 16, further including:
a die including an active surface and a backside surface, wherein the die is against the interface subsystem; and
a substrate, wherein the active surface faces the substrate.

19. A thermal interface comprising:
a plurality of aligned first heat transfer structures;
a second heat transfer structure, wherein the plurality of aligned first heat transfer structures is discretely disposed in the second heat transfer structure, and wherein the plurality of aligned first heat transfer structures is selected from graphite fibers, metal filaments, glass fibers, and combinations thereof.

20. The thermal interface according to claim 19, wherein the thermal interface includes a thickness in a range from about 100 Å to about 1,000 microns.

21. The thermal interface according to claim 19, further including:
a die including a backside surface, wherein the thermal interface is on the backside surface.

22. The thermal interface according to claim 19, further including:
an integrated heat spreader, wherein the thermal interface is on the integrated heat spreader.

23. The thermal interface according to claim 19, further including:
a die and an integrated heat spreader, wherein the thermal interface is between the die and the integrated heat spreader.

24. A packaging method comprising:
coupling a thermal management device to a die through an interface subsystem,
wherein the thermal management device is selected from an integrated heat spreader,
a heat pipe, and
a planar heat sink, and
wherein the interface subsystem includes
a plurality of aligned first heat transfer structures;
a second heat transfer structure, wherein the plurality of aligned first heat transfer structures is discretely disposed in the second heat transfer structure; and
bonding the interface subsystem to the thermal management device and the die.

25. The process according to claim 24, wherein the second heat transfer structure is selected from a metal, an organic composition, an inorganic dielectric, and a combination thereof, and wherein bonding the interface subsystem includes reflowing the metal and/or curing and hardening the organic composition.

26. The process according to claim 24, wherein coupling the thermal management device to the die through an interface subsystem further includes:
disposing the thermal management device against the interface subsystem; and
coupling the interface subsystem to the die.

27. The process according to claim 24, wherein coupling the thermal management device to the die through an interface subsystem further includes:
disposing the interface subsystem against the die; and
coupling the interface subsystem with the thermal management device.
